(19) United States
(12) Patent Application Publication
(10) Pub. No.: US 2012/0112727 A1
(43) Pub. Date: May 10, 2012

(54) ELECTRIC CURRENT MEASURING DEVICE, ELECTRIC CURRENT MEASURING METHOD, AND ELECTRIC CURRENT MEASURING PROGRAM

(75) Inventors: Hayato Motohashi, Tokyo (JP); Hirofumi Hirayama, Tokyo (JP); Naoki Nagashima, Tokyo (JP)

(73) Assignee: YAMATAKE CORPORATION, Tokyo (JP)

(21) Appl. No.: 13/383,376

(22) PCT Filed: Jun. 9, 2010
(86) PCT No.: PCT/JP2010/059756

§ 371 Date: Jan. 10, 2012

(30) Foreign Application Priority Data
Jul. 10, 2009 (JP) 2009-163537

(51) Int. Cl. G01R 19/25; G05F 3/04

(52) U.S. Cl. 323/304

(57) ABSTRACT

A current measurement device has a rectification unit rectifying an alternating-current signal, an A/D conversion unit converting an analog signal corresponding to a signal obtained by the rectification into a digital signal, an addition unit for adding digital signals corresponding to alternating-current signals during a sampling period among the digital signals obtained by the conversion, and a current value conversion unit for converting an additional value obtained by the addition by the addition unit into a current value using a current value conversion function. The sampling period is a common multiple of the periods of alternating-current signals of 50 Hz and 60 Hz, the current values of which are to be measured.

### CROSS REFERENCE TO PRIOR APPLICATIONS

This application is a U.S. National Phase application under 35 U.S.C. §371 of International Application No. PCT/JP2010/059756, filed on Jun. 9, 2010 and claims benefit of priority to Japanese Patent Application No. 2009-163537, filed on Jul. 10, 2009. The International Application was published in Japanese on Jan. 13, 2011 as WO 2011/004673 A1 under PCT Article 21(2). All of these applications are herein incorporated by reference.

### FIELD OF TECHNOLOGY

The present invention relates to an electric current measuring device, an electric current measuring method, and an electric current measuring program for measuring the value of an electric current.

### BACKGROUND

Within Japan, the frequency of an alternating current power signal (AC power supply) varies depending on the region, at 50 Hz in eastern Japan and 60 Hz in western Japan. Moreover, even when viewed globally, there are countries at 50 Hz and at 60 Hz. Consequently, with an electric current measuring device for measuring the value of the electric current, moving between regions that have different frequencies, for example, produces the need to change parameters, or the like, that are set according to the two frequencies, each time there is a move, which is time-consuming. Japanese Unexamined Patent Application Publication 2000-241458, below, discloses an electric current measuring device able to measure the value of an electric current without requiring the change of settings for the individual regions, through setting, as the AC current signal sampling period, 100 ms, which is the least common multiple of the periods for 50 Hz and 60 Hz.

However, in the hardware, such as A/D converters, and the like, for structuring the electric current measuring device, characteristics will differ depending on the hardware. Consequently, simply setting 100 ms, which is the least common multiple of the periods for 50 Hz and 60 Hz, as the sampling period for the AC current signal will run the risk of producing error in the measured value due to the effect of the hardware characteristics, and the like.

Given this, the present invention was created in order to solve the problem area with the present technology as described above, and the object thereof is to provide an electric current measuring device, an electric current measuring method, and an electric current measuring program able to improve the measurement accuracy.

### SUMMARY

The electric current measuring device according to the present example includes a current rectifying portion for performing current rectification on an alternating current signal; an A/D converting portion for converting, into a digital signal, a signal that has undergone current rectification by the current rectifying portion; a summing portion for performing a summation of a digital signal corresponding to the alternating current signal of a prescribed sampling period, of the digital signals converted by the A/D converting portion; and an electric current value converting portion for converting the summation value that has been summed by the summing portion into an electric current value using a prescribed electric current value converting function; wherein: the sampling period is a common multiple of each of the periods of a plurality of alternating current signals that are subject to measurement of the electric current values, having mutually differing periods; and the electric current value converting function is a function for assigning a one-to-one relationship between summation values and electric current values, wherein the coefficient or coefficients and constant or constants included in the electric current value converting function are a coefficient or coefficients and a constant or constants that are common to the plurality of alternating current signals.

The electric current measuring method according to an example includes a current rectifying step for performing current rectification on an alternating current signal; an A/D converting step for converting, into a digital signal, a signal that has undergone current rectification in the current rectifying step; a summing step for performing a summation of a digital signal corresponding to the alternating current signal of a prescribed sampling period, of the digital signals converted in the A/D converting step; and an electric current value converting step for converting the summation value that has been summed in the summing step into an electric current value using a prescribed electric current value converting function; wherein: the sampling period is a common multiple of each of the periods of a plurality of alternating current signals that are subject to measurement of the electric current values, having mutually differing periods; and the electric current value converting function is a function for assigning a one-to-one relationship between summation values and electric current values, wherein the coefficient or coefficients and constant or constants included in the electric current value converting function are a coefficient or coefficients and a constant or constants that are common to the plurality of alternating current signals.

The electric current measuring program according to the present example causes a procedure for performing current rectification on an alternating current signal; a procedure for converting, into a digital signal, a signal that has undergone current rectification; a procedure for performing a summation of a digital signal corresponding to the alternating current signal of a prescribed sampling period, of the converted digital signals; and a procedure for converting the summation value that has been summed into an electric current value using a prescribed electric current value converting function to be executed on a computer, wherein: the sampling period is a common multiple of each of the periods of a plurality of alternating current signals that are subject to measurement of the electric current values, having mutually differing periods; and the electric current value converting function is a function for assigning a one-to-one relationship between summation values and electric current values, wherein the coefficient or coefficients and constant or constants included in the electric current value converting function are a coefficient or coefficients and a constant or constants that are common to the plurality of alternating current signals.

The use of such structures makes it possible to define, as the sampling period, a common multiple of each of the plurality of AC current signals that are subject to electric current value measurements, each having different periods, for summing the digital signals corresponding to the AC current signals of the sampling periods, thus making it possible to cause the summing results, obtained from the results of the summation, to be identical for each individual AC current signal. This makes it possible to calculate the electric current values of a plurality of AC current signals having mutually different periods using electric current value converting functions that are common to all of the AC current signals, thus making it possible to reduce the effort in changing the settings for each AC current signal that has a different period. Moreover, because it is not only possible to provide the electric current value converting function that is used when measuring the electric current value with a one-to-one correspondence between the summation value and the electric current value, but also to have the coefficients and constants that are included in the electric current value converting function be coefficients and constants that are common for each of the AC current signals, thus making it possible to eliminate discrepancies through converting using the aforementioned electric current value converting function even when there are discrepancies in the correlation relationships between the summation values and the electric current values due to the characteristics of the AC current signals and the characteristics of the devices performing the measurement.

The present examples makes it possible to provide an electric current measuring device, an electric current measuring method, and an electric current measuring program able to improve the measurement accuracy.

### BRIEF DESCRIPTION OF THE DRAWINGS

FIG. 1 is a diagram illustrating the waveform of a signal after full-wave rectification in a 50 Hz AC current signal.

FIG. 2 is a diagram illustrating the waveform of a signal after full-wave rectification in a 60 Hz AC current signal.

FIG. 3 is a diagram illustrating a functional structure of an electric current measuring device.

FIG. 4 is a flowchart illustrating an operating procedure of a coefficient/constant setting process.

FIG. 5 is a flowchart illustrating an operating procedure of an electric current measuring process.

FIG. 6 is a structural diagram of a computer for executing an electric current measuring program.

### DETAILED DESCRIPTION

Examples are explained below in reference to the drawings. However, the example explained below is no more than an illustration, and does not exclude various modifications and applications to technologies not explicated below. That is, the present invention can be embodied in a variety of modified forms, in the scope that does not deviate from the spirit and intent thereof.

Prior to explaining an example, first the conditions that will cause the equality of physical quantities between periodic signals having different frequencies will be explained. First a physical quantity P of a periodic signal S that has a period T is calculated through the definite integral shown in Equation 1, below. M is a constant that is determined depending on the amplitude of the periodic signal S.

P=M ∫₀^{T} S(t)d t [Equation 1]

Next let us consider a plurality of periodic signals S₁, S₂, . . . , Sₙ for which the physical quantity P can be calculated through Equation 1, above. The periods of the individual periodic signals S₁, S₂, . . . , Sₙ are, respectively, T₁, T₂, . . . , Tₙ, where the sampling period when calculating .the physical quantity P is defined as C. When the individual periodic signals S₁, S₂, . . . , Sₙ fulfill the relationship indicated by Equation 2, below, then the individual periodic signals S₁, S₂, . . . , Sₙ constitute a plurality of AC current signals, having mutually differing periods, for which the electric current values can be measured using the electric current measuring device according to the examples. Here a period that is a common multiple of each of the periods T₁, T₂, . . . , Tₙ may be set as the sampling period C. Note that setting, as the sampling period C, a period that is the least common multiple of the individual periods T₁, T₂, . . . , Tₙ makes it possible to compress the time for measuring the physical quantity P. Moreover, it is assumed that the amplitudes of each of the periodic signals S₁, S₂, . . . , Sₙ are about the same.

$$\begin{matrix}{\int }_{C} {S}_{1} ( x ) d x = {\int }_{C}^{\\} {S}_{2} ( x ) d \dot{x} = … \\ = {\int }_{C} {S}_{n} ( x ) d x ⇒ \frac{C}{{T}_{1}} {\int }_{{T}_{1}} {S}_{1} ( x ) d x \\ = \frac{C}{{T}_{2}} {\int }_{{T}_{2}} {S}_{2} ( x ) d x = … \\ = \frac{C}{{T}_{n}} {\int }_{{T}_{n}} {S}_{n} ( x ) d x\end{matrix} \qquad [ Equation 2 ]$$

Each of the terms shown in Equation 2 indicates a physical quantity that is calculated through integrating the individual periodic signals S₁, S₂, . . . , Sₙ over the sampling period C. Consequently, the individual periodic signals that satisfy the relationship shown in Equation 2, above, although having mutually differing phases, have a relationship wherein the respective physical quantities that are calculated over the sampling period C will be equal to each other.

As the waveforms for the signals by which to be able to structure a set of periodic signals that fulfill the relationship illustrated in Equation 2, above, there are waveforms such as, for example, sine waves, half-rectified sine waves, fully-rectified sine waves, sine-squared waves, fully-rectified sine-squared waves, half-rectified sine-squared wave, square waves, triangle waves, trapezoidal waves, waveforms that are combinations of any number of these waveforms, or the like.

To cite a specific example of signals that structure a set of periodic signals that satisfies the relationship indicated in Equation 2, above, there is a 50 Hz AC current signal and a 60 Hz AC current signal. The reason why the 50 Hz AC current signal and the 60 Hz AC current signal form a set of periodic signals that satisfies the relationship in Equation 2 is explained below. Note that the physical quantity of the AC current signal corresponds to an electric current value.

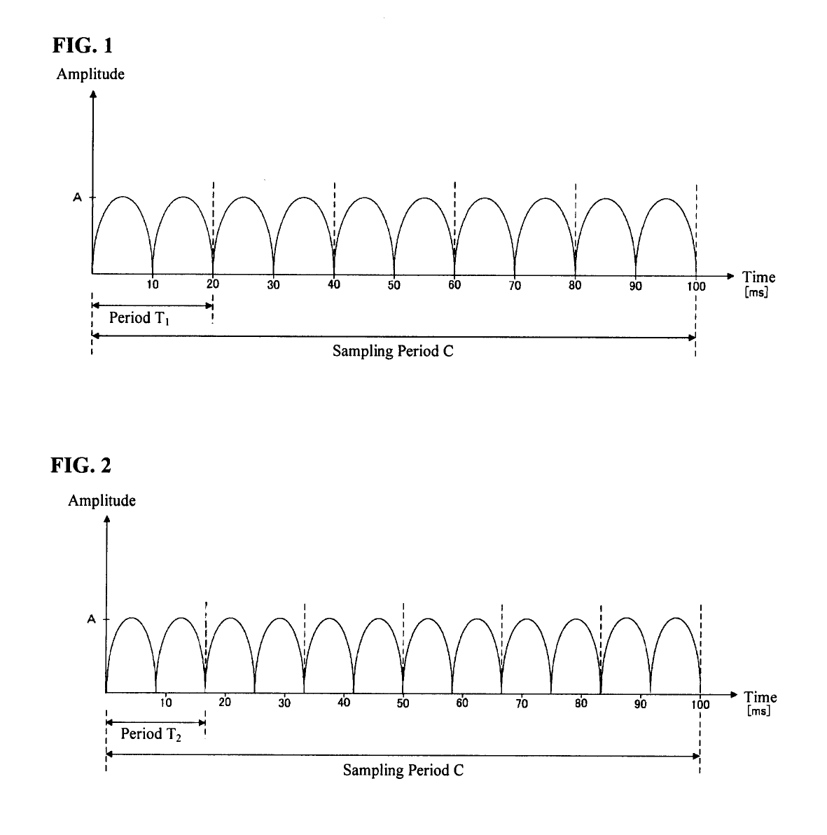

FIG. 1 is a diagram illustrating the waveform of a signal S₁ after full-wave rectification of a 50 Hz AC current signal (a sine wave with an amplitude of A: A|sine (100 π t|). FIG. 2 is a diagram illustrating the waveform of a signal S₂ after full-wave rectification of a 60 Hz AC current signal (a sine wave with an amplitude of A: A|sine (120 πt |). The period T₁ of the AC current signal at 50 Hz, which is the basis for the waveform illustrated in FIG. 1, is 1/50 s=20 ms. The period T₂ of the AC current signal at 60 Hz, which is the basis for the waveform illustrated in FIG. 2, is 1/60 s=16.66 . . . ms. Here the 100 ms that is the least common multiple of the periods for the 50 Hz and the 60 Hz is set as the sampling period C when calculating the electric current value.

Solving through assigning the waveform of Equation 1 to one side of Equation 2 results in Equation 3, below.

$$\begin{matrix} {\int }_{C} {S}_{1} ( x ) d x = \frac{C}{{T}_{1}} {\int }_{{T}_{1}} {S}_{1} ( x ) d x \\ = 5 {\int }_{0}^{1 / 50} A \vert sin ( 100 π t ) d t \\ = 20 A {\int }_{0}^{1 / 200} sin ( 100 π t ) d t \\ = - \frac{20 A}{100 π} [ cos ( 100 π t ) ] \text{?} \\ = \frac{A}{5 π}\end{matrix} \\ \text{?} \text{indicates text missing or illegible when filed} \qquad [ Equation 3 ]$$

Solving through assigning the waveform of Equation 2 to one side of Equation 2 results in Equation 4, below.

$$\begin{matrix} {\int }_{C} {S}_{2} ( x ) d x = \frac{C}{{T}_{2}} {\int }_{{T}_{2}} {S}_{2} ( x ) d x \\ = 6 {\int }_{0}^{1 / 50} A \vert sin ( 120 π t ) d t \\ = 24 A \text{?} sin ( 120 π t ) d t \\ = - \frac{24 A}{120 π} [ cos ( 120 π t ) ] \text{?} \\ = \frac{A}{5 π}\end{matrix} \\ \text{?} \text{indicates text missing or illegible when filed} \qquad [ Equation 4 ]$$

As illustrated in Equation 3, and Equation 4, above, in the waveform illustrated in FIG. 1 and the waveform illustrated in FIG. 2, the physical quantities measured over the sampling period C are both expressed by A/5π. This indicates that the 50 Hz AC current signal and 60 Hz AC current signal satisfy the relationship illustrated in Equation 2. Because of this, the 50 Hz AC current signal and the 60 Hz AC current signal constitute a plurality of AC current signal having mutually differing periods wherein the electric currents can be measured by the electric current measuring device according to the examples.

An electric current measuring device able to measure the respective electric current values of the AC current signals at 50 Hz and 60 Hz is explained below as an electric current measuring device according to the present examples. Note that for convenience in the explanation, in the present example a 50 Hz AC current signal and a 60 Hz AC current signal is used as the plurality of AC current signals having respectively different periods; however the AC current signals that can be applied to the invention in the present application are not limited thereto. The invention according to the application is applicable insofar as they are AC current signals that together form a set of periodic signals that fulfill the relationship indicated in Equation 2, above.

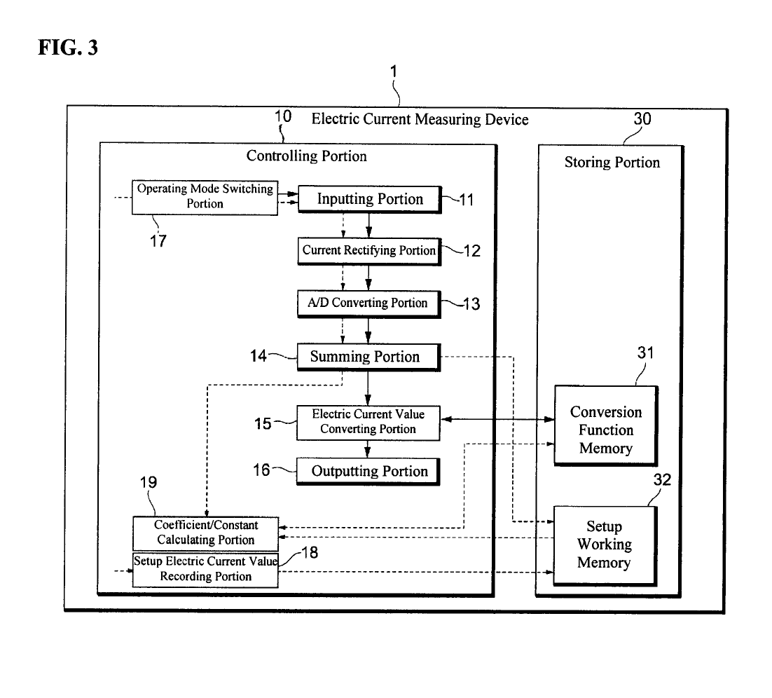

The functional structure of the electric current measuring device according to the present example is explained referencing FIG. 3. FIG. 3 is a functional structural diagram of an electric current measuring device. As illustrated in this figure, the electric current measuring device 1 includes a controlling portion 10 for controlling the device as a whole, in a storing portion 30 for storing the programs, data, and the like that are used in the various processes of the controlling portion 10.

The controlling portion 10 includes an inputting portion 11; a current rectifying portion 12; an A/D converting portion 13; a summing portion 14; an electric current value converting portion 15; an outputting portion 16, a operating mode switching portion 17; a setup electric current value recording portion 18; and a coefficient/constant calculating portion 19. The storing portion 30 comprises a conversion function memory 31 and a setup working memory 32.

Here the electric current measuring device 1 is provided with an electric current measuring mode and a parameter setup mode at as operating modes. The electric current measuring mode is a mode for measuring and outputting an electric current value for an AC current signal at 50 Hz or 60 Hz, inputted from the outside. The parameter setup mode is a mode for calculating and setting parameter values used at the time of the electric current measurement. The parameters used at the time of the electric current measurement are calculated using the 50 Hz or 60 Hz AC current signal inputted from the outside. As parameters that are used at the time of electric current measurement there are, for example, the coefficients and constants included in the electric current value converting function described below. The operating mode switching portion 17 switches between the electric current measuring mode and the parameter setup mode in accordance with an operating instruction that is inputted by the user.

When the operating mode is the electric current measuring mode, then the electric current is measured and outputted by the various portions that are the inputting portion 11, the current rectifying portion 12, the A/D converting portion 13, the summing portion 14, the electric current value converting portion 15, and the outputting portion 16. When the operating mode is the parameter setup mode, then the parameter values that are used when measuring the electric current are calculated and set by the various portions that are the setup electric current value recording portion 18, the inputting portion 11, the current rectifying portion 12, the A/D converting portion 13, the summing portion 14, and the coefficient/constant calculating portion 19.

The current rectifying portion 12 performs full-wave rectification of the 50 Hz or 60 Hz AC current signal that is inputted through the inputting portion 11 from the outside. Note that the current rectification of the AC current signal is not limited to full-wave current rectification, but rather may be half-wave current rectification instead. The A/D converting portion 13 converts into a digital signal the signal that has undergone full-wave current rectification by the current rectifying portion 12.

The summing portion 14 sums those digital signals, of the digital signals have been converted by the A/D converting portion 13, that correspond to the AC current signals within the sampling period. In the present example, 100 ms that is the least common multiple of the periods of 50 kHz and 60 kHz is set as the sampling period. The summing portion 14 stores, to the setup working memory 32, a summation value that is obtained from the result of the summation. The setup working memory 32 stores summation values, summed by the summing portion 14, in a quantity equal to the total of the numbers of coefficients and constants included in the electric current value converting function.

When the operating mode is the electric current measuring mode, the electric current value converting portion 15 converts the summation value, summed by the summing portion 14, into an electric current average value using the electric current value converting function, described below. The outputting portion 16 outputs, as the measurement result, the electric current average value converted by the electric current value converting portion 15.

When the operating mode is the parameter setup mode, the setup electric current value recording portion 18 records the electric current value, for which the input was indicated by the user, into the setup working memory 32. The setup working memory 32 stores setup electric current values, for setting up the coefficients and constants included in the electric current value converting function, described below, in a quantity equal to the number of these coefficients and constants. That is, the setup working memory 32 stores setup electric current values in association with summation values that are associated with those setup electric current values, in a quantity equal to the total of the numbers of coefficients and constants. Storing of the setup electric current values and summation values in a quantity equal to the total of the numbers of coefficients and constants is because taking data in a quantity that is equal to the total of the numbers of coefficients and constants that are unknown makes it possible to calculate the coefficients and constants that are unknown when, for example, the electric current value converting function is, for example, a function of degree n. However, depending on the structure of the electric current value converting function, the setup electric current values and summation values may be required in a quantity that is larger than the total of the numbers of coefficients and constants. Note that the content of the setup working memory 32 is reset when the operating mode is switched.

The coefficient/constant calculating portion 19, when the operating mode is the parameter setup mode, calculates the coefficients and constants included in the electric current value converting function, described below, and records them into the converting function memory 31. The converting function memory 31 stores the electric current value converting function, described below, and the coefficients and constants included in the electric current value converting function.

Here the controlling portion 10, physically, comprises, for example, a CPU, a memory, and an input/output interface. The memory includes a ROM for storing programs and data processed by the CPU, and a RAM that is used primarily as various types of working areas for control processes. These various elements are connected together through a bus. The CPU follows a program that is stored in the ROM to exchange various types of signals through the input/output interface to perform processes using the various data, and the like, in the RAM, to perform control such as the coefficient/constant setup process, the electric current measuring process, and the like. Moreover, the CPU performs control of the electric current measuring device 1 as a whole through outputting control signals to various drivers through the input/output interface.

The detail of the electric current value converting function is described below. The electric current value converting function is a converting function used when converting, into an electric current average value, the summation value that is summed by the summing portion 14. The electric current value converting function can be expressed, for example, on a coordinate plane that has the summation value as the X axis and the electric current average value as the Y axis. The electric current value converting function is not only determined so as to have a one-to-one relationship between the summation value and the electric current average value, but also the coefficients and constants included in the electric current value converting function are set to coefficients and constants that are the same for each individual AC current signal.

For the electric current value converting function, the electric current value converting function is determined through, for example, performing experiments, or the like, at the time of manufacturing the electric current measuring device 1, to find a correlation relationship between the inputted AC current signals and the output of electric current values, or the like, and is stored in the converting function memory 31. The coefficients and constants included in the electric current value converting function can be set and changed at any time as parameters.

While any given function can be used as the electric current value converting function, expression as a linear function makes it possible to suppress to two signals the number of signals inputted when calculating the coefficients and constants included in the electric current value converting function, making it possible to reduce the work in setting the parameters. Note that if the electric current value converting function cannot be expressed as a linear function, then the domain of the summation values that are expressed on the X axis in the electric current value converting function may be segmented finely, to approximate the functions in the individual domains as linear functions, enabling expression through the use of a plurality of approximated linear functions. Moreover, if the electric current value converting function is a quadratic function, then there will be two coefficients and one constant, and thus, when calculating the coefficients and the constants, signals for the total quantity of coefficients and the constant, that is, three signals, are inputted. Fundamentally, when the electric current value converting function is a function of a degree n, (n+1) signals will be inputted.

When the electric current value converting function is expressed as a linear function, then if, for example, the electric current average value is defined as IAV and the summation value is defined as X, then the function can be expressed as the equation given in Equation 5, below.

$${I}_{AV} = \frac{1}{T} {\int }_{T} i ( t ) d t = a X + b \qquad [ Equation 5 ]$$

Here a is the coefficient for the summation value X, and b is the constant. The coefficient a and the constant b are values that are the same for the AC current signals at both 50 Hz and 60 Hz. The reason why identical values can be used for the coefficients a and the constants b is that the AC current signals at 50 Hz and 60 Hz are included in a set of periodic signals that satisfies the relationship shown in Equation 2, above, making it possible to calculate the electric current values using a common electric current value converting function. That is, if the signals structure a set of periodic signals that satisfy the relationship illustrated in Equation 2, then the physical quantities calculated over the sampling period that is a common multiple of the periods of each of these signals will be equal. The fact that the physical quantities are equal is due to these electric current values being equal, making it possible to use the same function that includes the coefficient a and the constant b for the electric current value converting function as well.

Consequently, if the coefficient a and the constant b are calculated using either of the AC current signals and set as parameters, then there is no need to calculate and set again the coefficient a and the constant b using the other AC current signal. That is, once the parameters have been set in eastern Japan, for example, then even if moved to and used in western Japan, it is possible to measure the AC current without setting the parameters again.

The coefficient a can be calculated using the equation shown in Equation 6, below, where the constant b can be calculated using the equation shown in Equation 7, below.

$$\begin{matrix}a = \frac{{I}_{1} - {I}_{2}}{{X}_{1} - {X}_{2}} & [ Equation 6 ] \\ b = \frac{{I}_{2} {X}_{1} - {I}_{1} {X}_{2}}{{X}_{1} - {X}_{2}} & [ Equation 7 ]\end{matrix}$$

I₁ that is shown in Equation 6 and equation 7, above, is a first setup electric current value that is recorded in the setup working memory 32, X₁ is a first summation value that is recorded in the setup working memory 32 corresponding to the first setup electric current value I₁, I₂ is a second setup electric current value that is recorded in the setup working memory 32, and X₂ is a second summation value that is recorded in the setup working memory 32 corresponding to the second setup electric current value I₂.

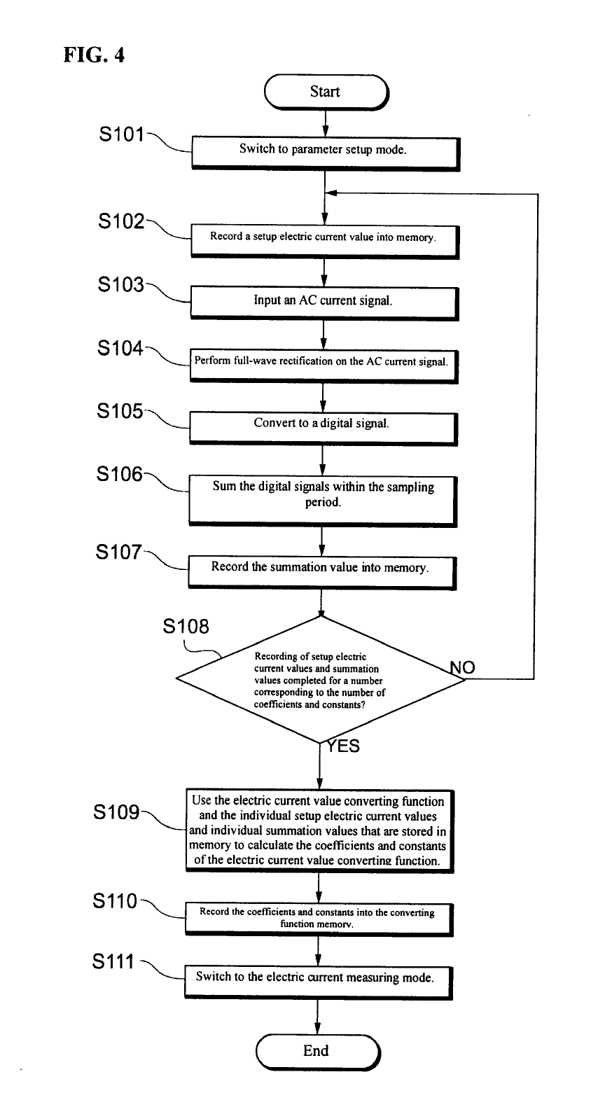

The operating procedure for the coefficient and constant setup process that is performed when setting the coefficient a and the constant b using the 50 Hz AC current signal will be explained in reference to FIG. 4.

Initially, the operating mode switching portion 17 switches the operating mode from the electric current measuring mode to the parameter setup mode in accordance with an operating instruction inputted by the user (Step S101).

Following this, the setup electric current value recording portion 18 records, into the setup working memory 32, as the setup electric current value, the average electric current value (a known electric current value) corresponding to the AC current signal inputted into the electric current measuring device 1, in accordance with an operation instruction inputted by the user (Step S102).

Following this, an AC current value is inputted from the inputting portion 11 (Step S103), and the current rectifying portion 12 performs full-wave rectification of the inputted AC current signal (Step S104).

Following this, the A/D converting portion 13 converts, into a digital signal, the signal that has been full-wave rectified by the current rectifying portion 12 (Step S105).

Following this, the summing portion 14 sums up the digital signals, of the digital signals converted by the A/D converting portion 13, corresponding to the AC current signals during the sampling period (Step S106), and records the summation value obtained as the result into the setup working memory 32 in correspondence with the setup electric current value recorded in Step S102 (Step S107).

Following this, the summing portion 14 evaluates whether or not setup electric current values and summation values of a quantity equal to the total of the numbers of coefficients and constants have been recorded into the setup working memory 32 (Step S108). If the evaluation is NO (Step S108: NO), then processing goes to Step S102, described above.

On the other hand, if it is evaluated in Step S108 that setup electric current values and summation values of a quantity equal to the total of the number of coefficients and the number of constants have been recorded in the setup working memory 32 (Step S108: YES), then the coefficient/constant calculating portion 19 uses the electric current value converting function stored in the converting function memory 31 and the individual setup electric current values and summation values that are recorded in the setup working memory 32 to calculate the coefficients a and the constants b included in the electric current value converting function (Step S109).

Following this, the coefficient/constant calculating portion 19 records, in the converting function memory 31, the coefficients a and constants b that have been calculated (Step S110).

Following this, the operating mode switching portion 17 switches the operating mode from the parameter setup mode to the electric current measuring mode in accordance with an operating instruction inputted by the user (Step S111).

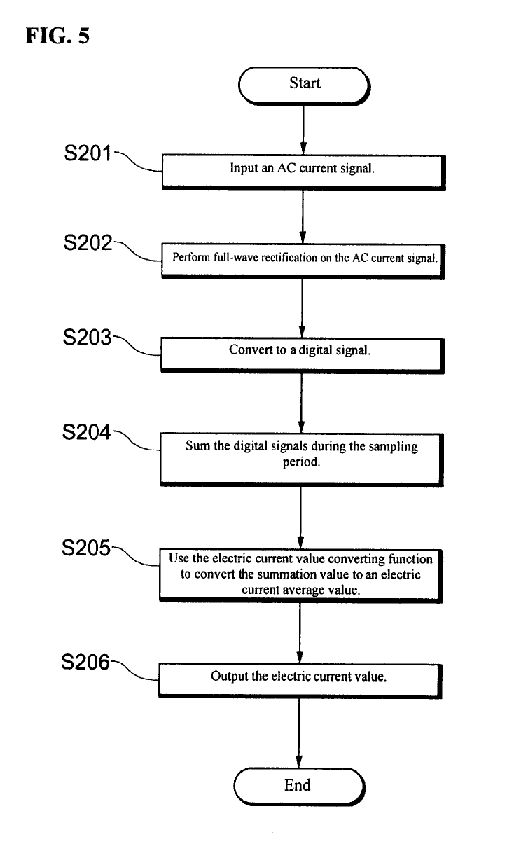

The operating procedure for the electric current measuring process in the present example is explained next in reference to FIG. 5. FIG. 5 is a flowchart illustrating an operating procedure of an electric current measuring process.

Initially, an AC current value is inputted from the inputting portion 11 (Step S201), and the current rectifying portion 12 performs full-wave rectification of the inputted AC current signal (Step S202).

Following this, the A/D converting portion 13 converts, into a digital signal, the signal that has been full-wave rectified by the current rectifying portion 12 (Step S203).

Following this, the summing portion 14 sums those digital signals, of the digital signals have been converted by the A/D converting portion 13, that correspond to the AC current signals within the sampling period (Step S204).

Following this, the electric current value converting portion 15 uses the electric current value converting function that is recorded in the converting function memory 31 to convert, into an electric current average value, the summation value that has been summed by the summing portion 14 (Step S205).

Following this, the outputting portion 16 outputs the electric current average value, which has been converted by the electric current value converting portion 15, to the outside as the electric current value measurement result (Step S206).

As described above, the electric current measuring device 1 according to the present example makes it possible to use, as a sampling period, a common multiple of each of the periods of the 50 Hz AC current signal and the 60 Hz AC current signal that are electric current values to be measured, to enable the summation of the digital signals corresponding to the AC current signals in this sampling period, thus making it possible to make the summation values, obtained as the result of summation, be the same for each of the AC current signals. This makes it possible to calculate the electric current values of a plurality of AC current signals having mutually different periods using electric current value converting functions that are common to all of the AC current signals, thus making it possible to reduce the effort in changing the settings for each AC current signal that has a different period.

Moreover, the electric current measuring device 1 according to the present example of embodiment is able not only to establish an electric current value converting function, used when measuring the electric current value, such that there will be a one-to-one correspondence between the summation values and the electric current average values, but is also able to establish the coefficients and constants that are included in the electric current value converting function as coefficients and constants that are common to each of the AC current signals. Consequently, even when there are discrepancies in the correlations between the summation values and the electric current average values due to the characteristics of the AC current signals or the hardware characteristics of the electric current measuring devices 1, it is possible to eliminate the discrepancies that are produced by individual electric current measuring devices 1, through converting using the aforementioned electric current value converting function. Doing so makes it possible to improve the measurement accuracy of the electric current measuring device 1.

Note that while in the example of embodiment set forth above an electric current value converting function was used to convert the summation value X into an electric current average value I_{AV}, there is no limitation to converting to an electric current average value I_{AV}, but instead the conversion may be into an electric current effective value I_{RMS}. In this case, the electric current value converting function may be expressed by the equation shown in Equation 8, below.

$$\text{?} = \sqrt{\frac{1}{T} {\int }_{T}^{i} {( t )}^{2} d t} = \sqrt{a X + b} \\ \text{?} \text{indicates text missing or illegible when filed} \qquad [ Equation 8 ]$$

The X indicated in Equation 8, above, is a value for a sum of squares. Consequently, the summing portion 14 in the present modified example performs summing after squaring the digital signals corresponding to the AC current signals within the sampling period, of the digital signals converted by the A/D converting portion 13. Note that having X represented by the sum-of-squares value causes aX+b to be a quadratic function, but taking the mean root of aX+b makes it possible to treat the electric current converting function shown in FIG. 8 essentially as a linear function. That is, the coefficient a can be calculated using the equation shown in Equation 6, above, and the constant b can be calculated using the equation shown in Equation 7, above, in the same manner as in the example set forth above.

Additionally, the structure of the electric current measuring device 1 in the example illustrated in FIG. 3 can be modified in a variety of ways without deviating from the spirit or intent of the present invention. For example, the functions of the controlling portion 10 of the electric current measuring device 1 may be incorporated into software, and the same functions as in the electric current measuring device 1 may be embodied through the execution thereof on a computer. An example of a computer for executing an electric current measuring program 171 that incorporates, as software, the various functions of the controlling portion 10 is presented below.

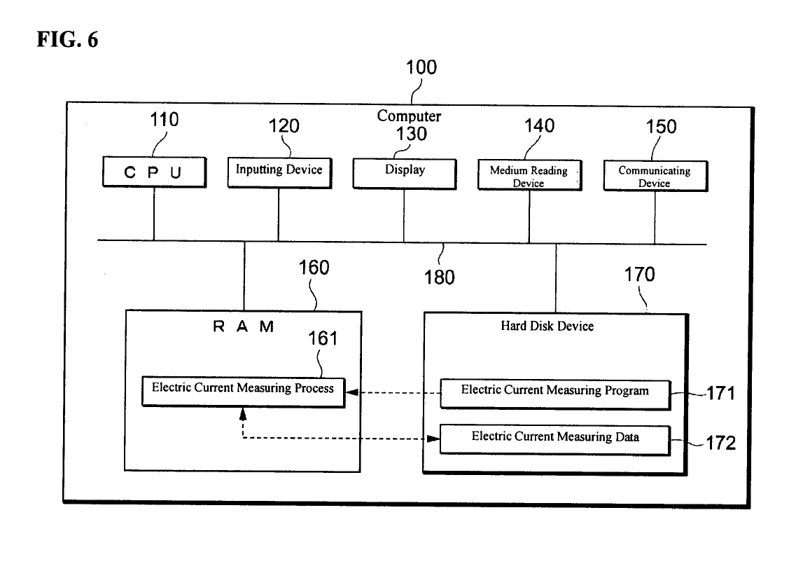

FIG. 6 is a structural diagram of a computer for executing an electric current measuring program 171. This computer 100 is structured from a CPU 110 for executing various types of calculation processes, an inputting device 120 for receiving the input of data from a user, a display 130 for displaying various types of information, a medium reading device 140 for reading programs, or the like, from a recordable medium, a communicating device 150 for exchanging data with other computers over a network, a RAM 160 for storing various types of information temporarily, and a hard disk device 170 are connected together through a bus 180.

The hard disk device 170 stores an electric current measuring program 171 that has the same functions as the controlling portion 10 illustrated in FIG. 3, and electric current measuring data 172 corresponding to the various types of data stored in the storing portion 30 illustrated in FIG. 3. Note that the electric current measuring data 172 may be distributed as needed, to be stored in another computer that is connected through a network.

The CPU 110 reads out the electric current measuring program 171 from the hard disk device 170 and deploys it to the RAM 160, where the electric current measuring program 171 functions as an electric current measuring process 161. The electric current measuring process 161 deploys to the RAM 160, as needed, the electric current measuring data 172 that is read out from the hard disk device 170, to execute various processes based on the deployed data.

Note that the electric current measuring program 171 need not necessarily be stored on the hard disk device 170. For example, an electric current measuring program 171 that is stored on a storage medium such as a CD-ROM, or the like, may be read out and executed by the computer 100. Moreover, the electric current measuring program 171 may be stored on another computer that is connected to the computer 100 through telephone lines, the Internet, a LAN, a WAN, or the like, and the electric current measuring program 171 may be read out by the computer 100 from the other computer and executed.

Moreover, the present invention may be applied also to measurements of AC signals other than electric currents. For example, it can be understood easily that the same effects of operation as in the present invention can be obtained also in the case of application of the present invention to measurements of a plurality of waveform signals (sounds, vibrations, light, or the like) wherein the frequencies are known in advance.

The electric current measuring device, electric current measuring method, and electric current measuring program according to the present invention can be applied to improving measurement accuracies.

1. An electric current measuring device comprising:
a current rectifying portion performing current rectification on an alternating current signal;
an AD converting portion converting, into a digital signal, a signal that has undergone current rectification by the current rectifying portion;
a summing portion performing a summation of a digital signal corresponding to the alternating current signal of a prescribed sampling period, of the digital signals converted by the A/D converting portion; and
an electric current value converting portion converting the summation value that has been summed by the summing portion into an electric current value using a prescribed electric current value converting function; wherein:
the sampling period is a common multiple of each of the periods of a plurality of alternating current signals that are subject to measurement of the electric current values, having mutually differing periods; and
the electric current value converting function is a function for assigning a one-to-one relationship between summation values and electric current values, wherein the coefficient and constant included in the electric current value converting function are a coefficient and a constant that are commonly used for the plurality of alternating current signals.

2. The electric current measuring device as set forth in claim 1, further comprising:
a coefficient and constant calculating portion calculating the coefficient and constant included in the electric current value converting function using a known electric current value and a summation value corresponding to one of the alternating current signals that produces the known electric current value; and
a storing portion storing the coefficient or coefficients and constant or constants calculated by the coefficient and constant calculating portion,

3. The electric current measuring device as set forth in claim 1, wherein:
the electric current value converting function is a linear function.

4. The electric current measuring device as set forth in claim 1, wherein:
the plurality of alternating current signals are a 50 Hz alternating current signal and a 60 Hz alternating current signal.

5. An electric current measuring method comprising:
a current rectifying step performing current rectification on an alternating current signal;
an A/D converting step converting, into a digital signal, a signal that has undergone current rectification in the current rectifying step;
a summing step performing a summation of a digital signal corresponding to the alternating current signal of a prescribed sampling period, of the digital signals converted in the A/D converting step; and
an electric current value converting step converting the summation value that has been summed in the summing step into an electric current value using a prescribed electric current value converting function; wherein:
the sampling period is a common multiple of each of the periods of a plurality of alternating current signals that are subject to measurement of the electric current values, having mutually differing periods; and
the electric current value converting function is a function for assigning a one-to-one relationship between summation values and electric current values, wherein the and constant included in the electric current value converting function are a coefficient or coefficients and a constant or constants that are common to the plurality of alternating current signals.

6. A computer-readable medium having stored thereon a plurality of sequences of instructions which, when executed by one or more processors cause an electronic device to execute:
a procedure for performing current rectification on an alternating current signal;
a procedure for converting, into a digital signal, a signal that has undergone current rectification;
a procedure for performing a summation of a digital signal corresponding to the alternating current signal of a prescribed sampling period, of the converted digital signals; and
a procedure for converting the summation value that has been summed into an electric current value using a prescribed electric current value converting function to be executed on a computer, wherein:
the sampling period is a common multiple of each of the periods of a plurality of alternating current signals that are subject to measurement of the electric current values, having mutually differing periods; and
the electric current value converting function is a function for assigning a one-to-one relationship between summation values and electric current values, wherein the coefficient or coefficients and constant or constants included in the electric current value converting function are a coefficient or coefficients and a constant or constants that are common to the plurality of alternating current signals.
